(19) United States
(12) Patent Application Publication
(10) Pub. No.: US 2026/0190577 A1
(43) Pub. Date: Jul. 2, 2026

(54) STRETCHABLE DISPLAY DEVICE AND METHOD OF FABRICATING THE SAME

(71) Applicant: LG Display Co., Ltd., Seoul (KR)

(72) Inventors: Yeon-Jun OH, Paju-si (KR); Do-Joong KIM, Paju-si (KR); Jun-Hyuk SONG, Paju-si (KR); Tae-Hyun KIM, Paju-si (KR); Sung-Joon MIN, Paju-si (KR)

(73) Assignee: LG Display Co., Ltd., Seoul (KR)

(21) Appl. No.: 19/386,820

(22) Filed: Nov. 12, 2025

(30) Foreign Application Priority Data
Dec. 26, 2024 (KR) 10-2024-0197266

(51) Int. Cl. H10H 29/49; H10H 29/01

(52) U.S. Cl. CPC H10H 29/49; H10H 29/012

(57) ABSTRACT

In some examples, a stretchable display device includes a first display panel having a first base substrate including a first rigid part, a first soft part and a first bent end, a first light emitting element on the first base substrate, a first horizontal stretchable line extending along a first direction, and a first pad disposed on a first surface of the first base substrate and on the first bent end; and a first organic material pattern disposed on a second surface of the first base substrate and on the first bent end. A first pixel is provided at the first rigid part, and the first soft part is disposed outside the first rigid part, where the first horizontal stretchable line is connected to the first pixel and disposed on the first soft part, and where the first pad is connected to an end of the first horizontal stretchable line.

### CROSS-REFERENCE TO RELATED APPLICATIONS

The present application claims the benefit of and priority to Korean Patent Application No. 10-2024-0197266 filed in the Republic of Korea on Dec. 26, 2024, the entire contents of which are incorporated herein by reference for all purposes.

### BACKGROUND

### 1. Technical Field

The present disclosure relates to a display device, and particularly to, for example, without limitation, a stretchable display device and a method of fabricating the same being capable of reducing a bezel area and improving a production yield.

### 2. Description of Related Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

The stretchable display device is a display that can freely transform the shape of a screen without distortion even when the screen is increased in size, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device may include a rigid part in which a pixel is disposed and a soft part in which a connection line connecting the pixels is disposed. The rigid part may not be stretched, and the soft part may be stretched.

The description of related art should not be considered prior art merely because it is mentioned in or associated with this section. The description of related art includes information that describes one or more aspects of the subject technology, and the description in this section does not limit the scope of the present disclosure.

### SUMMARY

One or more aspects of the present disclosure are directed to a stretchable display device and a method of fabricating the same that substantially obviate one or more of the problems associated with the limitations and disadvantages of the related conventional art.

An aspect of the present disclosure is to provide a stretchable display device and a method of fabricating the same being capable of improving a production yield by bonding a plurality of display panels on which a micro-LED is transferred.

An aspect of the present disclosure is to provide a stretchable display device and a method of fabricating the same being capable of easily removing a carrier substrate by forming an organic material pattern (e.g., an organic sacrificing pattern).

An aspect of the present disclosure is to provide a stretchable display device and a method of fabricating the same being capable of reducing a bezel area and preventing a damage on a pad.

Additional features and advantages of the present disclosure are set forth in the description which follows, and will be apparent from the description, or evident by practice of the present disclosure. The aspects and other advantages of the present disclosure are realized and attained by the features described herein as well as in the appended drawings.

To achieve these and other advantages in accordance with the purpose of the embodiments of the present disclosure, as described herein, an aspect of the present disclosure is a stretchable display device comprising a first display panel including a first base substrate including a first rigid part, a first soft part and a first bent end, a first light emitting element on the first base substrate, a first horizontal stretchable line extending along a first direction and a first pad disposed on a first surface of the first base substrate and on the first bent end; and a first organic material pattern disposed on a second surface of the first base substrate and on the first bent end, wherein a first pixel is provided at the first rigid part, and the first soft part is disposed outside the first rigid part, wherein the first horizontal stretchable line is connected to the first pixel and disposed on the first soft part, and wherein the first pad is connected to an end of the first horizontal stretchable line.

Another aspect of the present disclosure is a method of fabricating a stretchable display device comprising forming a first inorganic sacrificing layer on a first surface of a first carrier substrate; forming a first panel on the first inorganic sacrificing layer, wherein the first panel includes: a first base substrate including a first rigid part, a first soft part and a first bent end; a first light emitting element on the first base substrate and a first horizontal stretchable line disposed on the first soft part, and wherein a first pixel is provided at the first rigid part, and the first horizontal stretchable line is connected to the first pixel; forming a first hole exposing the first base substrate by etching the first carrier substrate and the first inorganic sacrificing layer at a portion of the first soft part; forming a first organic material pattern in the first hole; bending the first base substrate based on the first hole; and irradiating a laser to the first hole to remove a portion of the first carrier substrate, a portion of the first inorganic sacrificing layer, a portion of the first base substrate, and a portion of the first horizontal stretchable line.

It is to be understood that both the foregoing general description and the following detailed description are examples and explanatory and are intended to further explain the present disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a schematic plan view of a stretchable display device according to a first embodiment of the present disclosure.

FIG. 2 is a schematic plan view of a display panel for a stretchable display device according to the first embodiment of the present disclosure.

FIG. 3 is a schematic cross-section view of a stretchable display device according to the first embodiment of the present disclosure.

FIGS. 4A to 4H are schematic cross-sectional views illustrating a fabricating processes of a stretchable display device according to the first embodiment of the present disclosure.

FIGS. 5A and 5B are schematic cross-sectional views illustrating a fabricating processes of a stretchable display device according to another embodiment of the present disclosure.

FIG. 6 is a schematic cross-section view of a stretchable display device according to the first embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When “including,” “having,” “consisting,” and the like are used in this specification, other parts may be added unless “only” is used. When a component is expressed in the singular, cases including the plural are included, unless expressly stated otherwise. In one or more examples, unless expressly stated otherwise, an element may be one or more elements; and an element may include a plurality of elements.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

It will be understood that, although the terms “first,” “second,” etc. may be used herein to describe various elements, these elements should not be limited by these terms. These terms are merely used to refer to one element separately from another. For example, a first element could be termed a second element, and, similarly, a second element could be termed a first element, without departing from the scope of the present disclosure.

Reference will now be made in detail to some of the examples and preferred embodiments, which are illustrated in the accompanying drawings.

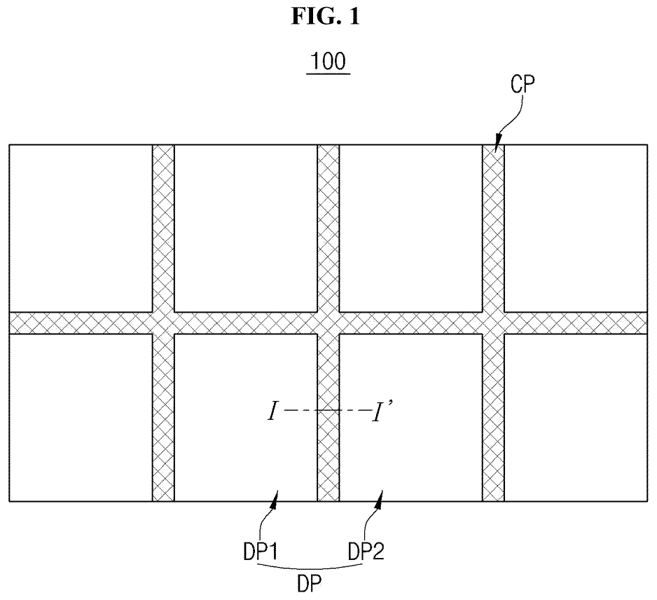

FIG. 1 is a schematic plan view of a stretchable display device according to a first embodiment of the present disclosure.

As shown in FIG. 1, a stretchable display device 100 of the present disclosure includes a first display panel DP1 and a second display panel DP2 at a side of the first display panel DP1. The stretchable display device 100 may further include a panel bonding portion (e.g., a panel adhering portion or a panel joining portion) CP between the first and second display panels DP1 and DP2.

Each of the first and second display panels DP1 and DP2 may be a micro-LED panel including a micro-LED as a light emitting element. After a micro-LED is transferred onto a base substrate to form each of the first and second display panels DP1 and DP2, the first and second display panels DP1 and DP2 are bonded to each other to provide the stretchable display device 100.

The stretchable display device 100 includes two or more display panels DP1 and DP2, and there is no limitation in a number of the display panels.

In the stretchable display device 100 of the present disclosure, after the display panel DP is formed by transferring the micro-LED onto the base substrate, a defect detection process is performed to each display panel DP. Accordingly, the production yield of the display panel DP is increased, and the production cost of the display panel DP is decreased.

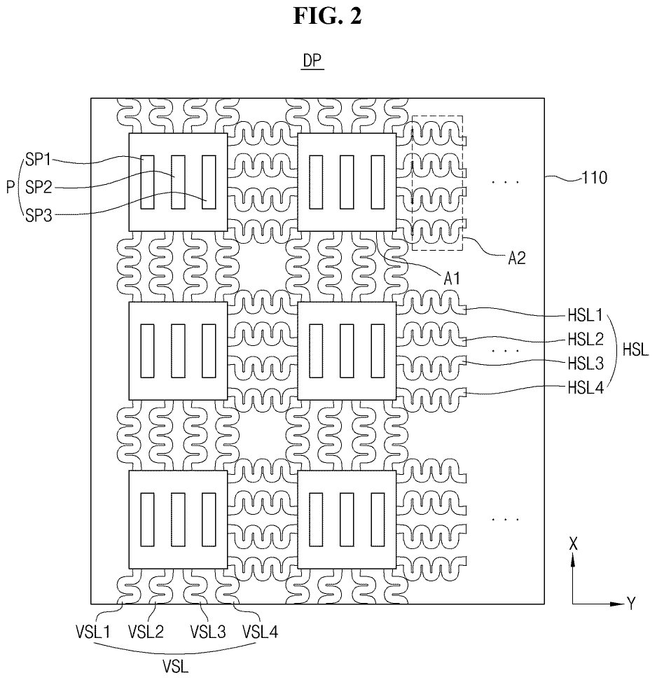

FIG. 2 is a schematic plan view of a display panel for a stretchable display device according to the first embodiment of the present disclosure.

As shown in FIG. 2, the display panel DP includes the base substrate 110, and a rigid part A1 and a soft part A2 are provided (or defined) in a first region of the base substrate 110. The rigid part A1 is not stretched, and the soft part A2 can be stretched. The display panel DP can be stretched along a first direction X and a second direction Y.

A plurality of rigid parts A1 each having an island shape are provided. The rigid parts A1 are spaced apart from each other in the first and second directions X and Y. For example, the rigid part A1 may have a square shape.

A pixel P including a plurality of subpixels SP1, SP2 and SP3 are provided in the rigid part A1. For example, a first subpixel SP1, a second subpixel SP2 and a third subpixel SP3 may be provided in the rigid part A1, and the first to third subpixels SP1, SP2 and SP3 may be red, green and blue subpixels, respectively. The first to third subpixels SP1, SP2 and SP3 may be arranged along the second direction Y.

Each of the first to third subpixels SP1, SP2 and SP3 may include a light emitting element and at least one transistor. In addition, each of the first to third subpixels SP1, SP2 and SP3 may further include at least one capacitor.

The soft part A2 is positioned between adjacent rigid parts A1 in the first and second directions X and Y. For example, the soft part A2 may be disposed to surround the rigid part A1.

A stretchable lines VSL and HSL (e.g., a stretchable signal line) connecting adjacent pixels P are provided in the soft part A2. The stretchable lines VSL and HSL may include a plurality of signal lines (e.g., a plurality voltage lines) such as a gate line, a data line, a high level line (e.g., high-level voltage line), a low level line (e.g., a low-level voltage line), an emission signal line or a reference voltage line.

A vertical stretchable line VSL (e.g., a first stretchable line) may include first, second, third and fourth vertical stretchable lines VSL1, VSL2, VSL3 and VSL4. The vertical stretchable line VSL extends along the first direction X. For example, the first vertical stretchable line VSL1 may be the reference voltage line, and each of the second to fourth vertical stretchable lines VSL2 to VSL4 may be first to third date lines for applying a data signal to the first to third subpixels SP1 to SP3, respectively. For example, each of the first to fourth vertical stretchable lines VSL1 to VSL4 may include a first line connected to one side of the pixel P and a second line connected to the other side of the pixel P.

A horizontal stretchable line HSL (e.g., a second stretchable line) may include first, second, third and fourth horizontal stretchable lines HSL1, HSL2, HSL3 and HSL4. The horizontal stretchable line HSL extends along the second direction Y. For example, the first horizontal stretchable line HSL1 may be the high level line, and the second horizontal stretchable line HSL2 may be the gate line. The third horizontal stretchable line HSL3 may be the emission signal line, and the fourth horizontal stretchable line HSL4 may be the low level line. For example, each of the first to fourth horizontal stretchable lines HSL1 to HSL4 may include a first line connected to one side of the pixel P and a second line connected to the other side of the pixel P.

The stretchable lines VSL and HSL may include at least one curved portion. For example, the stretchable lines VSL and HSL may have a wave structure and include a plurality of wave shapes.

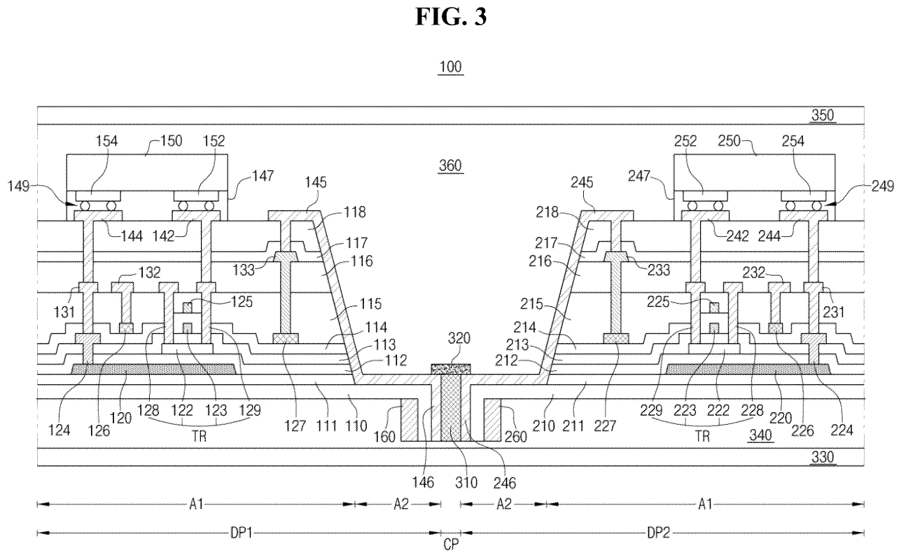

FIG. 3 is a schematic cross-section view of a stretchable display device according to the first embodiment of the present disclosure.

Referring to FIG. 3 with FIGS. 1 and 2, the stretchable display device 100 includes the first and second display panels DP1 and DP2, which are bonded to each other through the panel bonding portion CP. In each of the first and second display panels DP1 and DP2, an end of the first base substrate 110 and an end of the second base substrate 210 are bent so that a pad of the first display panel DP1 and a pad of the second display panel DP2 face to each other.

The first display panel DP1 includes a first base substrate 110 including a first rigid part A1, where a pixel P is disposed, a first soft part A2 outside of the first rigid part A1, and a bent end, a first light emitting element 150 on the first base substrate 110, a horizontal stretchable line (such as a first horizontal stretchable line) 145 connected to the pixel and extending along a first direction and a first pad 146 connected to an end of the horizontal stretchable line 145. The horizontal stretchable line 145 is disposed in the first soft part A2, and the first pad 146 is disposed on a first surface of the bent end of the first base substrate 110.

The second display panel DP2 includes a second base substrate 210 including a second rigid part A1, where a pixel P is disposed, a second soft part A2 outside of the second rigid part A1, and a bent end, a second light emitting element 250 on the second base substrate 210, a second horizontal stretchable line 245 connected to the pixel and extending along a first direction and a second pad 246 connected to an end of the horizontal stretchable line (such as a second horizontal stretchable line) 245. The horizontal stretchable line 245 is disposed in the second soft part A2, and the second pad 246 is disposed on a first surface of the bent end of the second base substrate 210.

The first pad 146 of the first display panel DP1 and the second pad 246 of the second display panel DP2 are electrically connected to each other so that a signal can be applied to the horizontal stretchable line 145 of the first display panel DP1 and the horizontal stretchable line 245 of the second display panel DP2 by a single driving unit (e.g., a single driver). For example, the stretchable display device 100 may further include a metal bonding pattern (e.g., a metal adhering pattern or a metal joining pattern) 310 connecting the first pad 146 of the first display panel DP1 and the second pad 246 of the second display panel DP2 and disposed in the panel bonding portion CP.

In addition, the stretchable display device 100 may further include an organic bonding pattern 320 disposed in the panel bonding portion CP and covering the metal bonding pattern 310.

The first and second display panels DP1 and DP2 are bonded through the panel bonding portion CP, and a first soft substrate (e.g., a first flexible substrate) 330 and a second soft substrate 350 are attached to one side of the first and second display panels DP1 and DP2 and the other side of the first and second display panels DP1 and DP2 by a first adhesive layer 340 and a second adhesive layer 360, respectively. As a result, the stretchable display device 100 is provided.

In the stretchable display device 100 of the present disclosure, an end of the first display panel DP1 and an end of the second display panel DP2 are bent. Accordingly, the first adhesive layer 340 may have a first thickness at a center of the first display panel DP1 and a second thickness, which is smaller than the first thickness, at an edge of the first display panel DP1. In addition, the first adhesive layer 340 may have a third thickness at a center of the second display panel DP2 and a fourth thickness, which is smaller than the third thickness, at an edge of the second display panel DP2.

The first soft substrate 330 may have a first distance from the first base substrate 110 at a center of the first display panel DP1 and a second distance, which is smaller than the first distance, from the first base substrate 110 at an edge of the first display panel DP1. In addition, the first soft substrate 330 may have a third distance from the second base substrate 210 at a center of the second display panel DP2 and a fourth distance, which is smaller than the third distance, from the second base substrate 210 at an edge of the second display panel DP2.

In the stretchable display device 100 of the present disclosure, at least one of insulating layers on the base substrates 110 and 210 are removed. Accordingly, the second adhesive layer 360 may have a fifth thickness at a center of the first display panel DP1 and a sixth thickness, which is greater than the fifth thickness, at an edge of the first display panel DP1. In addition, the second adhesive layer 360 may have a seventh thickness at a center of the second display panel DP2 and an eighth thickness, which is greater than the seventh thickness, at an edge of the second display panel DP2.

A first organic material pattern (e.g., a first organic material sacrificing pattern) 160 corresponding to the first pad 146 is disposed on a rear surface of the first base substrate 110 of the first display panel DP1, and a second organic material pattern 260 corresponding to the second pad 246 is disposed on a rear surface of the second base substrate 210 of the second display panel DP2. The damage onto the first and second base substrates 110 and 210 and/or the first and second pads 146 and 246 after a carrier substrate is removed in a fabricating process of the first and second display panels DP1 and DP2 can be prevented by the first and second organic material patterns 160 and 260. Namely, the first and second base substrates 110 and 210, on which the first and second pads 146 and 246 are provided, are respectively supported by the first and second organic material patterns 160 and 260 so that the damage onto the first and second base substrates 110 and 210 and/or the first and second pads 146 and 246 can be prevented.

A thickness of the first organic material pattern 160 may be equal to or greater than a thickness of the bent end of the first base substrate 110, and a thickness of the second organic material pattern 260 may be equal to or greater than a thickness of the bent end of the second base substrate 210. Accordingly, the first and second base substrates 110 and 210 and the first and second pads 146 and 246 can be firmly supported by the first and second organic material patterns 160 and 260.

The first and second organic material patterns 160 and 260 are positioned on an inner surface of the bent end of the first and second base substrates 110 and 210.

In a horizontal direction, a length of the first organic material pattern 160 may be equal to a length of the bent end of the first base substrate 110, and a length of the second organic material pattern 260 may be equal to a length of the bent end of the second base substrate 210. The bent end of the first base substrate 110, the first pad 146, the second pad 246 and the bent end of the second base substrate 210 are positioned between the first and second organic material patterns 160 and 260. In addition, the metal bonding pattern 310 may be further positioned between the first and second organic material patterns 160 and 260. In a vertical direction, a length of the metal bonding pattern 310 may be greater than a length of each of the first and second organic material patterns 160 and 260.

Two surfaces (e.g., two sides) of the first organic material pattern 160 contact the first base substrate 110, the other two surfaces of the first organic material pattern 160 contact the first adhesive layer 340. Two surfaces (e.g., two sides) of the second organic material pattern 260 contact the second base substrate 210, the other two surfaces of the second organic material pattern 260 contact the first adhesive layer 340.

In the stretchable display device 100, the second display panel DP2 is disposed at a first side of the first display panel DP1. The stretchable display device 100 may further include a third display panel disposed at a second side, which is adjacent to the first side, of the first display panel DP1.

In this case, the first display panel DP1 may further include a first vertical stretchable line connected to the pixel and extending along a second direction, which is perpendicular to the first direction, a third pad connected to an end of the first vertical stretchable line and a third organic material pattern disposed on a second surface of a bent end of the first base substrate 110. The first vertical stretchable line may be disposed in the first soft part A2, and the third pad may be disposed on a first surface of the bent end of the first base substrate 110.

The third display panel may include a third base substrate including a third rigid part, where a pixel P is disposed, a third soft part outside of the third rigid part, and a bent end, a third light emitting element on the third base substrate, a second vertical stretchable line connected to the pixel and extending along the second direction, a fourth pad connected to an end of the second vertical stretchable line and a fourth organic material pattern disposed on a second surface of the bent end of the third base substrate. The second vertical stretchable line is disposed in the third soft part, and the fourth pad is disposed on a first surface of the bent end of the third base substrate to face the third pad.

In addition, the stretchable display device 100 may further include a second metal bonding pattern between the third pad of the first display panel DP1 and the fourth pad of the third display panel and a second organic bonding pattern covering the second metal bonding pattern.

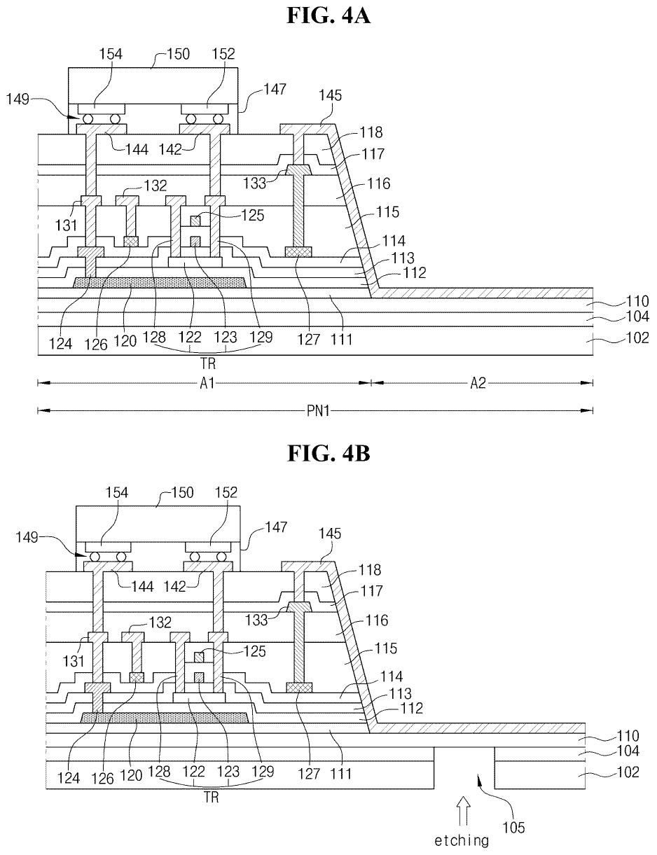

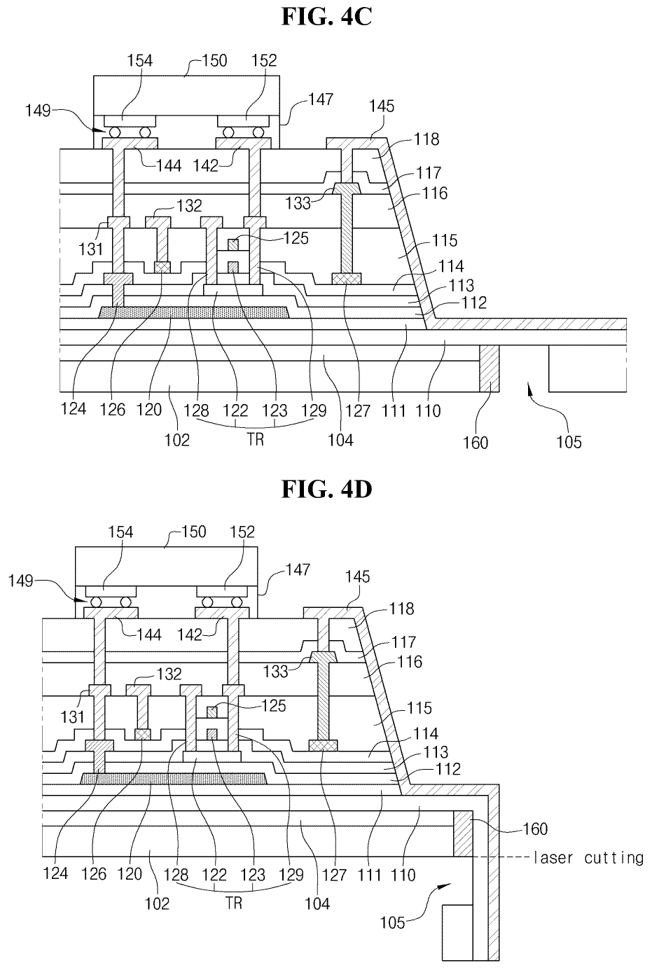

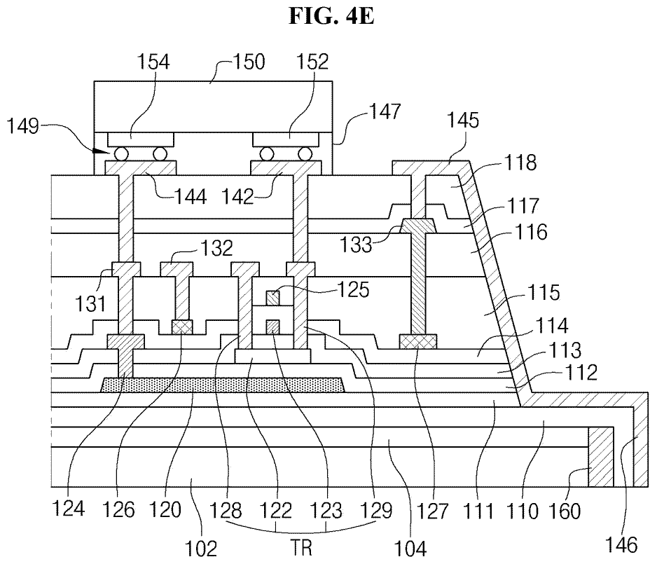

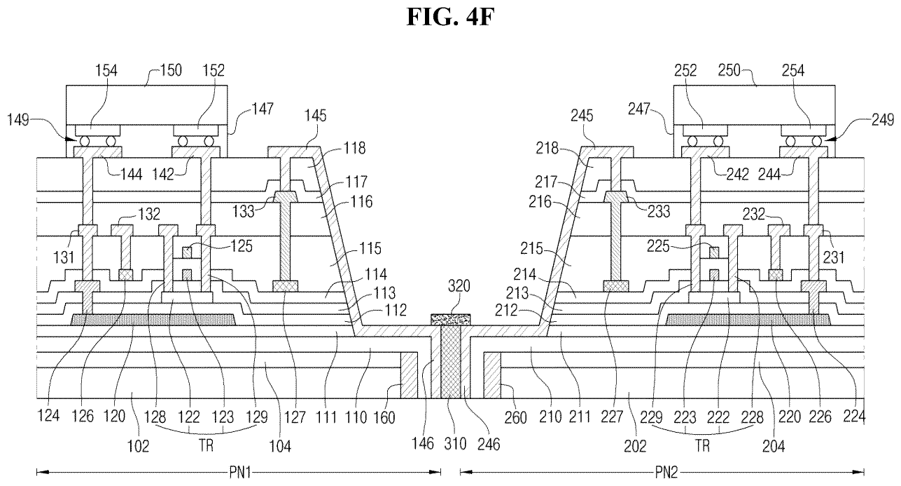

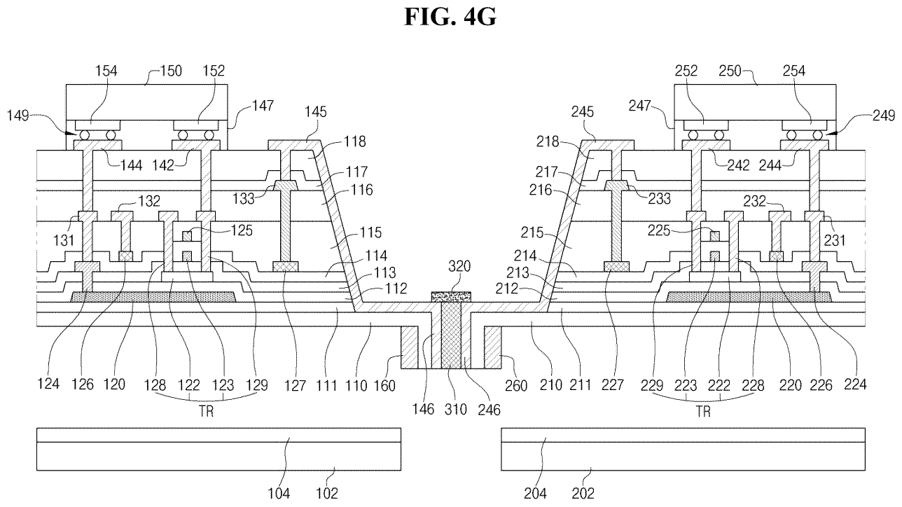

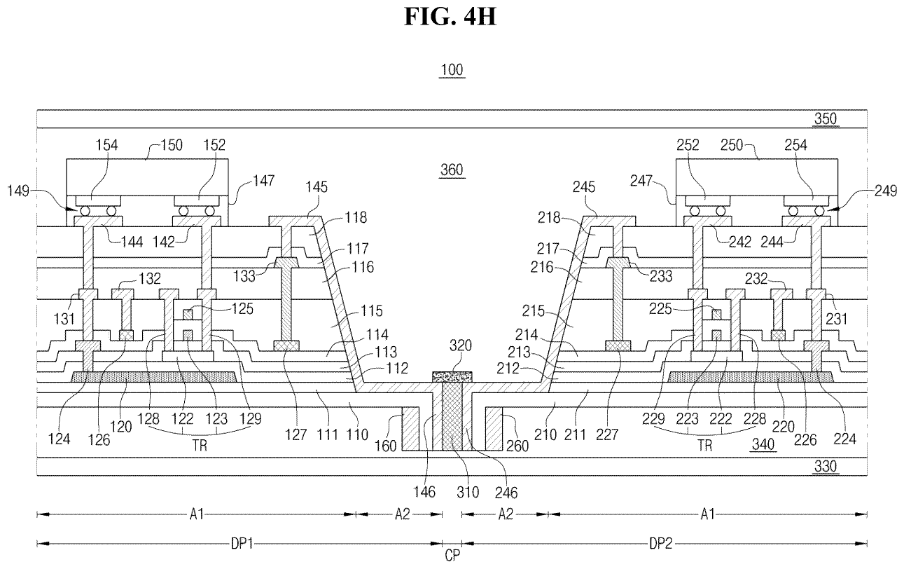

FIGS. 4A to 4H are schematic cross-sectional views illustrating a fabricating processes of a stretchable display device according to the first embodiment of the present disclosure. Referring to FIGS. 4A to 4H with FIGS. 2 and 3, the fabricating processes of the stretchable display device will be explained.

As shown in FIG. 4A, a step of forming an inorganic sacrificing layer 104 on a carrier substrate 102 and a step of forming a first panel on the inorganic sacrificing layer 104 are performed. The first panel includes a base substrate 110 including a rigid part A1, where a pixel is disposed, and a soft part A2 outside the rigid part A1, a light emitting element 150 over the base substrate 110 and a horizontal stretchable line 145 connected to the pixel and disposed in the soft part A2.

First, an inorganic material is deposited onto the carrier substrate 102 to form the inorganic sacrificing layer 104.

The inorganic sacrificing layer 104 is formed to separate the carrier substrate from the display panel DP by irradiating a laser beam. Namely, as described below, the inorganic sacrificing layer 104 and the carrier substrate 102 are separated from the display panel DP by a laser lift-off process. For example, the inorganic sacrificing layer 104 may be formed of amorphous silicon.

The base substrate 110 is provided on the inorganic sacrificing layer 104. The base substrate 110 includes a first base part and a second base part. The first base part corresponds to the rigid part A1, and the second base part corresponds to the soft part A2.

The base substrate 110 includes (or is formed of) a rigid material having a relatively low flexibility. The base substrate 110 may have a flexibility being lower than each of the first and second soft substrates 330 and 350. For example, the base substrate 110 may be formed of a polyimide-based resin or an epoxy-based resin.

The base substrate 110 has a relatively high elastic modulus, and the elastic modulus of the base substrate 110 may be higher than the elastic modulus of the first and second soft substrates 330 and 350. For example, the elastic modulus of the base substrate 110 may be at least 1000 times higher than the elastic modulus of the first and second soft substrates, but it is not limited thereto.

An inorganic insulating material is deposited on the base substrate 110 to form a first buffer layer 111 as a first insulating layer. For example, the first buffer layer 111 may include an inorganic insulating material, e.g., silicon nitride (SiNx), silicon oxide (SiOx) or silicon oxynitride (SiON).

A conductive material is deposited on the first buffer layer 111, and a mask process is performed to form a light shielding layer 120 on the first buffer layer 111 and in the rigid part A1. The light shielding layer 120 may include a metal, e.g., aluminum (Al), copper (Cu), molybdenum (Mo), titanium (Ti), chromium (Cr), nickel (Ni), tungsten (W) or their alloys.

An inorganic insulating material is deposited on the light shielding layer 120 to form a second buffer layer 112 as a second insulating layer. For example, the second buffer layer 112 may include an inorganic insulating material, e.g., silicon nitride (SiNx), silicon oxide (SiOx) or silicon oxynitride (SiON).

A semiconductor material is deposited on the second buffer layer 112, and a mask process is performed to form a semiconductor layer 122 on the second buffer layer 112. The semiconductor layer 122 may overlap the light shielding layer 120. The light to the semiconductor layer 122 may be blocked by the light shielding layer 120 so that the thermal degradation of the semiconductor layer 122 can be prevented.

The semiconductor layer 122 may include a channel region and a source region at a first side of the channel region and a drain region at a second side of the channel region.

The semiconductor layer 122 may include an oxide semiconductor material. Alternatively, the semiconductor layer may include poly-crystalline silicon.

An inorganic insulating material is deposited on the semiconductor layer 122 to form a gate insulating layer 113 as a third insulating layer. For example, the gate insulating layer 113 may include an inorganic insulating material, e.g., silicon nitride (SiNx), silicon oxide (SiOx) or silicon oxynitride (SiON).

A conductive material is deposited on the gate insulating layer 113, and a mask process is performed to form a gate electrode 123 and a first connection electrode 124 on the gate insulating layer 113.

The gate electrode 123 overlaps the semiconductor layer 122 and corresponds to a center of the semiconductor layer 122. As a result, the gate electrode 123 may overlap the light shielding layer 120.

The first connection electrode 124 is spaced apart from the semiconductor layer 122 and overlaps the light shielding layer 120. The first connection electrode 124 may contact the light shielding layer 120 through a contact hole in the second buffer layer 112 and the gate insulating layer 113.

Each of the gate electrode 123 and the first connection electrode 124 may include a metal, e.g., Al, Cu, Mo, Ti, Cr, Ni, W or their alloys.

An inorganic insulating material is deposited on the gate electrode 123 and the first connection electrode 124 to form a first interlayer insulating layer 114 as a fourth insulating layer. For example, the first interlayer insulating layer 114 may include an inorganic insulating material, e.g., silicon nitride (SiNx), silicon oxide (SiOx) or silicon oxynitride (SiON).

A conductive material is deposited on the first interlayer insulating layer 114, and a mask process is performed to form an auxiliary electrode 125, an auxiliary line 126 and a pad electrode 127 on the first interlayer insulating layer 114.

Each of the auxiliary electrode 125, the auxiliary line 126 and the pad electrode 127 may include a metal, e.g., Al, Cu, Mo, Ti, Cr, Ni, W or their alloys.

An inorganic insulating material is deposited or an organic insulating material is coated on the auxiliary electrode 125, the auxiliary line 126 and the pad electrode 127, and a mask process is performed to form a second interlayer insulating layer 115 as a fifth insulating layer. For example, the second interlayer insulating layer 115 may include an inorganic insulating material, e.g., silicon nitride (SiNx), silicon oxide (SiOx) or silicon oxynitride (SiON), or an organic insulating material, e.g., photo-acryl or benzocyclobutene.

A conductive material is deposited on the second interlayer insulating layer 115, and a mask process is performed to form a source electrode 128, a drain electrode 129, a second connection electrode 131 and a power line 132 on the second interlayer insulating layer 115.

The source electrode 128 and the drain electrode 129 contact a first edge and a second edge of the semiconductor layer 122, respectively, through a contact hole in the first and second interlayer insulating layers 114 and 115. The gate electrode 123, the semiconductor layer 122, the source electrode 128 and the drain electrode 129 constitute a thin film transistor (TFT) TR.

The second connection electrode 131 is spaced apart from the TFT TR and overlaps the first connection electrode 124. The second connection electrode 131 contacts the first connection electrode 124 through a contact hole in the first and second interlayer insulating layers 114 and 115.

The power line 132 contacts the auxiliary line 126 through a contact hole in the second interlayer insulating layer 115. For example, the power line 132 may be a signal line for providing a low potential voltage (ELVSS). The power line 132 or the auxiliary line 126 may be connected to the light shielding layer 120. Namely, the low potential voltage may be provided into the light shielding layer 120.

Each of the source electrode 128, the drain electrode 129, the second connection electrode 131 and the power line 132 may include a metal, e.g., Al, Cu, Mo, Ti, Cr, Ni, W or their alloys.

An inorganic insulating material is deposited or an organic insulating material is coated on the source electrode 128, the drain electrode 129, the second connection electrode 131 and the power line 132 to form a third interlayer insulating layer 116 as a sixth insulating layer. For example, the third interlayer insulating layer 116 may include an inorganic insulating material, e.g., silicon nitride (SiNx), silicon oxide (SiOx) or silicon oxynitride (SiON), or an organic insulating material, e.g., photo-acryl or benzocyclobutene.

A conductive material is deposited on the third interlayer insulating layer 116, and a mask process is performed to form an auxiliary pad 133 on the third interlayer insulating layer 116. The auxiliary pad 133 contacts the pad electrode 127 through a contact hole in the second and third interlayer insulating layers 115 and 116. The auxiliary pad 133 may include a metal, e.g., Al, Cu, Mo, Ti, Cr, Ni, W or their alloys.

An inorganic insulating material is deposited on the auxiliary pad 133 to form a passivation layer 117 as a seventh insulating layer. For example, the passivation layer 117 may include an inorganic insulating material, e.g., silicon nitride (SiNx), silicon oxide (SiOx) or silicon oxynitride (SiON).

An organic insulating material is coated on the passivation layer 117, and a mask process is performed to form a planarization layer 118 as an eighth insulating layer. The step difference may be planarized by the planarization layer 118, and the planarization layer 118 may have a substantially flat top surface. The planarization layer 118 may include an organic insulating material, e.g., photo-acryl or benzocyclobutene.

A conductive material is deposited on the planarization layer 118, and a mask process is performed to form a horizontal stretchable line 145 on the planarization layer 118. An end of the horizontal stretchable line 145 is disposed on the planarization layer 118 in the rigid part A1 and is connected to the auxiliary pad 133 through a contact hole in the planarization layer 118 and the passivation layer 117. The horizontal stretchable line 145 extends into the soft part A2 to contact an upper surface of the base substrate 110 in the soft part A2. The horizontal stretchable line 145 may contact side surfaces of the first and second buffer layers 111 and 112, the gate insulating layer 113, the first to third interlayer insulating layers 114, 115 and 116, the passivation layer 117 and the planarization layer 118.

The horizontal stretchable line 145 may be one of the first to fourth horizontal stretchable lines HSL1, HSL2, HSL3 and HSL4.

In the process forming the horizontal stretchable line 145, the others of the first to fourth horizontal stretchable lines HSL1, HSL2, HSL3 and HSL4 connected to one side of the pixel are formed. In addition, the vertical stretchable lines VSL1, VSL2, VSL3 and VSL4, which is connected to the other side of the pixel and extends into the soft part A2, are formed.

In addition, a first electrode 142 and a second electrode 144 may be formed on the planarization layer 118. The first and second electrodes 142 and 144 may be formed in the process of forming the horizontal stretchable line 145. The first electrode 142 is connected to the drain electrode 129. The first electrode 142 may be connected to the drain electrode 129 through a contact hole in the planarization layer 118, the passivation layer 117 and the third interlayer insulating layer 116. The second electrode 144 is connected to the second connection electrode 131. The second electrode 144 may be connected to second connection electrode 131 through a contact hole in the planarization layer 118, the passivation layer 117 and the third interlayer insulating layer 116.

Each of the first to fourth horizontal stretchable lines HSL1 to HSL4, the first to fourth vertical stretchable lines VSL1 to VSL4 and the first and second electrodes 142 and 144 may be formed of a conductive material, e.g., metal. For example, each of the first to fourth horizontal stretchable lines HSL1 to HSL4, the first to fourth vertical stretchable lines VSL1 to VSL4 and the first and second electrodes 142 and 144 may be formed of one of Al, Cu, Mo, Ti, Cr, Ni, W or their alloys. The first to fourth horizontal stretchable lines HSL1 to HSL4, the first to fourth vertical stretchable lines VSL1 to VSL4 and the first and second electrodes 142 and 144 may be formed in the same process.

Next, by performing a mask process, e.g., an etching process, the base substrate 110, the first and second buffer layers 111 and 112, the gate insulating layer 113, the first to third interlayer insulating layers 114 to 116, the passivation layer 117 and the planarization layer 118 between the first to fourth horizontal stretchable lines HSL1 to HSL4, between the first to fourth vertical stretchable lines VSL1 to VSL4 and between the horizontal stretchable line HSL and the vertical stretchable line VSL are removed. Namely, the base substrate 110, the first and second buffer layers 111 and 112, the gate insulating layer 113, the first to third interlayer insulating layers 114 to 116, the passivation layer 117 and the planarization layer 118 remain under the first to fourth horizontal stretchable lines HSL1 to HSL4 and the first to fourth vertical stretchable lines VSL1 to VSL4 in the rigid part A1.

Next, an adhesive layer 147 including a plurality of conductive balls 149 is formed on the first and second electrodes 142 and 144, and a light emitting diode 150 as a light emitting element is transferred onto the adhesive layer 147. The light emitting diode 150 is electrically connected to the first and second electrodes 142 and 144 through the adhesive layer 147 including the plurality of conductive balls 149. The adhesive layer 147 may be an anisotropic conductive film (ACF).

The light emitting diode 150 includes a third electrode 152 and a fourth electrode 154 on a lower side. The third electrode 152 may be a p-electrode, and the fourth electrode 154 may be an n-electrode. For example, the third electrode 152 may be an anode, and the fourth electrode 154 may be a cathode. The light emitting diode 150 may be provided in the form of a light emitting diode chip including an n-electrode, an n-type layer, an active layer, a p-type layer, and a p-electrode. The light-emitting diode 150 may be a micro-LED.

The third electrode 152 overlaps the first electrode 142, and the fourth electrode 154 overlaps the second electrode 144. The third electrode 152 is electrically connected to the first electrode 142 through the conductive ball 149 in the adhesive layer 147, and the fourth electrode 154 is electrically connected to the second electrode 144 through the conductive ball 149 in the adhesive layer 147.

Next, as shown in FIG. 4B, the carrier substrate 102 and the inorganic sacrificing layer 104 in a portion of the soft part A2 are etched to form an etching hole 105. As a result, a rear surface of the base substrate 110 is exposed through the etching hole 105.

Next, as shown in FIG. 4C, an organic material is coated and cured to form an organic material pattern (e.g., an organic sacrificing pattern) 160 on a side surface of the carrier substrate 102 and a side surface of the inorganic sacrificing layer 104 and in the etching hole 105. Each of the side surface of the carrier substrate 102 and the side surface of the inorganic sacrificing layer 104, on which the organic material pattern 160 is formed, is adjacent to the rigid part A1. A thickness of the organic material pattern 160 from the side surface of the inorganic sacrificing layer 104 may be greater than a thickness of the base substrate 110 from an upper surface of the inorganic sacrificing layer 104.

For example, the organic material pattern 160 may be formed of one of a xylene-based compound, a toluene-based compound, an ethylacetate-based compound, a terpene-based compound and a turpentine-based compound, but it is not limited thereto. In an embodiment of the present disclosure, the organic material pattern 160 may be formed of one of xylene, toluene, ethylacetate, terpene and turpentine.

Next, as shown in FIGS. 4D and 4E, an end of each of the carrier substrate 102, the inorganic sacrificing layer 104, the base substrate 110 and the horizontal stretchable line 145 are bent based on the etching hole 105, and a laser is irradiated corresponding to the etching hole 105 to remove the carrier substrate 102, the inorganic sacrificing layer 104, the base substrate 110, and the horizontal stretchable line 145 outside the etching hole 105 (laser cutting). The horizontal stretchable line 145 at the end of the base substrate 110 is defined as a pad 146.

A first panel PN1 is fabricated by the processes in FIGS. 4A to 4E. The processes in FIGS. 4A to 4E are performed to form a second panel PN2. For example, the second panel PN2 includes components similar to those of the first panel PN1, such as a first buffer layer 211 as a first insulating layer, a second buffer layer 212 as a second insulating layer, a gate insulating layer 213 as a third insulating layer, a first interlayer insulating layer 214 as a fourth insulating layer, a second interlayer insulating layer 215 as a fifth insulating layer, a third interlayer insulating layer 216 as a sixth insulating layer, a passivation layer 217 as a seventh insulating layer, a planarization layer 218 as an eighth insulating layer, TFT TR including a semiconductor layer 222, a gate electrode 223, a source electrode 228 and a drain electrode 229, a light shielding layer 220, a first connection electrode 224, an auxiliary electrode 225, an auxiliary line 226, a pad electrode 227, a second connection electrode 231, a power line 232, an auxiliary pad 233, a first electrode 242, a second electrode 244, a second horizontal stretchable line 245, a second pad 246, an adhesive layer 247 including a plurality of conductive balls 249, light emitting diode 250 including a third electrode 252 and a fourth electrode 254 on a lower side, as well as a second organic material pattern 260. The configurations of these components in the second panel PN2 are similar to those of the corresponding components in the first panel PN1, and thus will be described briefly below.

Next, as shown in FIG. 4F, the first panel PN1 and the second panel PN2 are disposed so that the pad 146 being the end of the horizontal stretchable line 145 in the first panel PN1 faces the pad 246 being the end of the horizontal stretchable line 245 in the second panel PN2. As a result, the pad 146 being the end of the horizontal stretchable line 145 in the first panel PN1 and the pad 246 being the end of the horizontal stretchable line 245 in the second panel PN2 are electrically connected to each other.

In an embodiment of the present disclosure, the pad 146 being the end of the horizontal stretchable line 145 in the first panel PN1 and the pad 246 being the end of the horizontal stretchable line 245 in the second panel PN2 may be bonded (e.g., adhered or joined) through a metal bonding pattern 310. For example, the metal bonding pattern 310 may be formed of one of Al, Cu, Mo, Ti, Cr, Ni, W or their alloys.

In an embodiment of the present disclosure, an organic bonding pattern 320 may be formed to correspond to a boundary of the first and second panels PN1 and PN2. When the metal bonding pattern 310 is formed, the organic bonding pattern 320 may cover the metal bonding pattern 310.

The organic bonding pattern 320 may be formed of an organic material having a refractive index in a range of 1.4 to 1.6. For example, the organic bonding pattern 320 may be formed of one of a urethane-based compound, a butadiene-based compound, an acryloligomer-based compound, an acryl-based compound and an epoxy-based compound, but it is not limited thereto.

The display quality degradation resulting from the recognition of the boundary between the first panel PN1 and the second panel PN2 can be prevented by the organic bonding pattern 320.

Next, as shown in FIG. 4G, a laser is irradiated onto a rear surface of the carrier substrate (e.g., a first carrier substrate) 102 of the first panel PN1 and a rear surface of the carrier substrate (e.g., a second carrier substrate) 202 of the second panel PN2 to separate the first carrier substrate 102 and the inorganic sacrificing layer 104 from the base substrate 110 and the second carrier substrate 202 and the inorganic sacrificing layer 204 from the base substrate 210. Namely, the first carrier substrate 102, the inorganic sacrificing layer 104, the second carrier substrate 202 and the inorganic sacrificing layer 204 are removed by a laser lift off process.

The inorganic sacrificing layers 104 and 204, which are formed of amorphous silicon, are removed with the first and second carrier substrate 102 and 202 by the lase irradiation. Namely, hydrogen gas is generated from the inorganic sacrificing layers 104 and 204 by the laser irradiation, the separation occurs at the interface between the inorganic sacrificing layers 104 and 204 and the base substrates 110 and 210.

The organic material pattern 160, which is formed of the above material, is not removed or partially removed in the LLO process. As a result, the organic material pattern 160 remains on a rear surface of each end of the base substrates 110 and 210.

Namely, a photo-oxidation reaction occurs due to electron transfer in the organic material of each of the organic material patterns 160 and 260, and the electron is transferred to an excited state to continuously generate radical ions with oxygen (O₂). For example, when the organic material is toluene, the methyl group and the benzene ring are broken by the laser irradiation, and the C-H bond of the benzene ring reacts with OH radicals or electrons. As a result, the organic material pattern is photo-decomposed.

Accordingly, after the LLO process is completed, at least a portion of the organic material patterns 160 and 260 remains on the rear surface of each end of the base substrates 110 and 210.

When the LLO process is performed without the organic material patterns 160 and 260, the carrier substrates 102 and 202 may not be separated from the base substrates 110 and 210 in the etching hole 105.

In addition, when an inorganic material pattern (e.g., an inorganic sacrificing pattern) is formed in the etching hole instead of the organic material patterns 160 and 260, the pads 146 and 246 may be damaged. Namely, since the base substrates 110 and 210 in the stretchable display device 100 have a relatively thin profile (e.g., a relatively small thickness), the pads 146 and 246 are supported by only the base substrates 110 and 210 after the LLO process is completed. As a result, the pads 146 and 246 and/or the base substrates 110 and 210 may be damaged. However, in the stretchable display device 100 of the present disclosure, since the organic material patterns 160 and 260 corresponding to the pads 146 and 246 are presented on the rear surface of the base substrates 110 and 210 after the LLO process is completed, the base substrates 110 and 210 and the pads 146 and 246 are sufficiently supported by the organic material patterns 160 and 260 so that the damage on the pads 146 and 246 and/or the base substrates 110 and 210 can be prevented.

In addition, since the inorganic material pattern, which is formed of amorphous silicon, is formed by a deposition process, the inorganic material pattern cannot be formed at a side surface of the carrier substrate 102 in the etching hole 105. The deposition process for forming the inorganic material pattern of amorphous silicon is performed in high temperature, the TFT TR and/or the light emitting element 150 may be thermally damaged. However, since the organic material patterns 160 and 260 can be formed by a coating process with low temperature, the organic material patterns 160 and 260 can be formed on the side surface of the carrier substrate 102 without a damage onto the TFT TR and/or the light emitting element 150.

Each of the organic material patterns 160 and 260 may further include a pigment to increase an absorbing rate of the laser beam in the LLO process. For example, the pigment may include at least one of a black pigment, a red pigment, a green pigment and a blue pigment.

Next, as shown in FIG. 4H, a first soft substrate 330 is attached to the base substrates 110 and 210 by using a first adhesive layer 340, and a second soft substrate 350 is attached onto to the light emitting elements 150 and 250 by using a second adhesive layer 360.

The stretchable display device 100 including the first display panel DP1 and the second display panel DP2, which are attached by a panel bonding portion CP, can be fabricated by the processes in FIGS. 4A to 4H.

In an embodiment of the present disclosure, the stretchable display device 100 including the first display panel DP1 and the second display panel DP2, which are attached by a panel bonding portion CP, can be fabricated by the processes in FIGS. 4A to 4G without the process of attaching the first and second soft substrates 330 and 350 in FIG. 4H.

In the present disclosure, the stretchable display device 100 is provided by attaching the first and second panels PN1 and PN2, which are independently fabricated, by the panel bonding portion CP, the defects in the elements, e.g., the light emitting element, can be inspected at each of the panels PN1 and PN2 stage. Accordingly, the production yield of the stretchable display device 100 can be improved, and the production cost can be reduced.

In addition, the carrier substrates can be easily separated by the LLO process due to the organic material patterns 160 and 260.

Moreover, since the organic material patterns 160 and 260 are presented on the rear surface of the base substrates 110 and 210 in the display panels DP1 and DP2, respectively, the damage on the pads 146 and 246 on the bent base substrates 110 and 210 can be prevented.

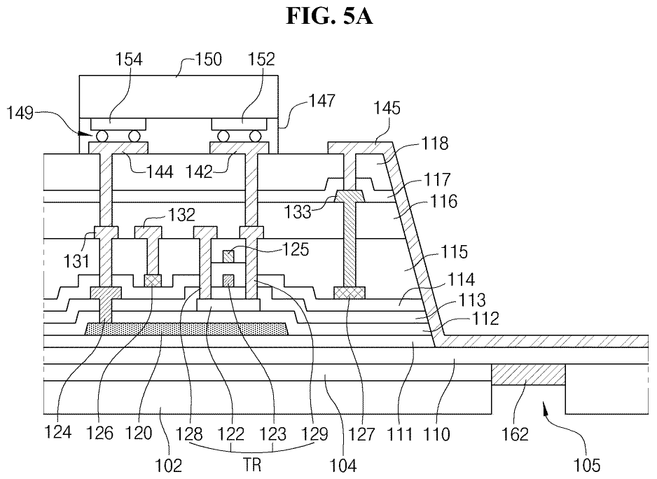

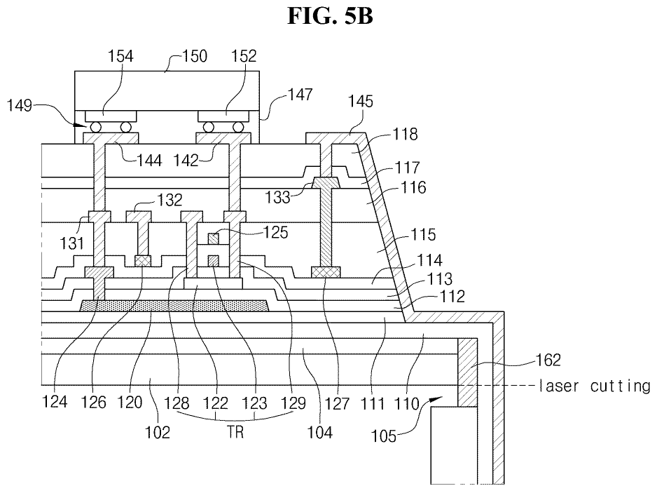

FIGS. 5A and 5B are schematic cross-sectional views illustrating a fabricating processes of a stretchable display device according to another embodiment of the present disclosure.

The fabricating process in FIGS. 5A and 5B has a difference in a process of forming the organic material pattern from the fabricating process in FIGS. 4A to 4H.

As shown in FIG. 5A, an organic material pattern 162 is formed to cover a rear surface of the base substrate 110 exposed through the etching hole 105. Namely, the organic material pattern 162 may have an area (e.g., a planar area) being equal to the etching hole 105.

Next, as shown in FIG. 5B, a laser is irradiated onto the etching hole 105, the carrier substrate 102, the inorganic sacrificing layer 104, the organic material pattern 162, the base substrate 110 and the horizontal stretchable line 145 outside a portion of the etching hole 105 are removed (laser cutting).

Next, the processes in FIGS. 4F to 4H or FIGS. 4F to 4G are performed to fabricate the stretchable display device 100.

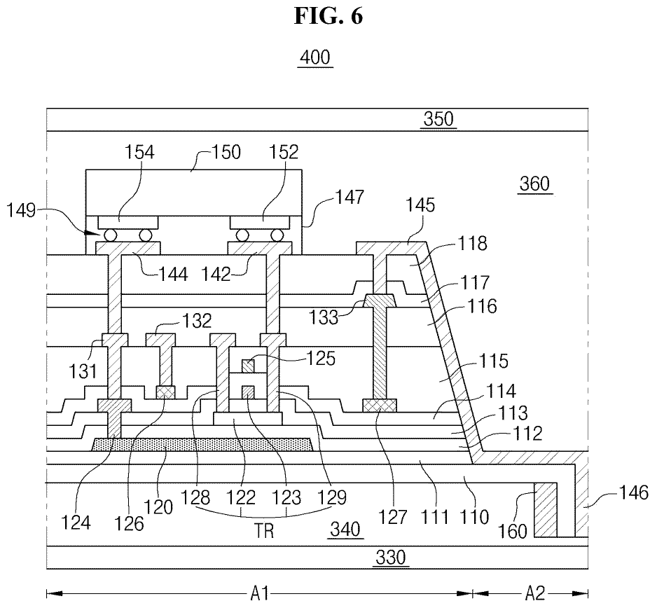

FIG. 6 is a schematic cross-section view of a stretchable display device according to the first embodiment of the present disclosure.

As shown in FIG. 6, a stretchable display device 400 includes a display panel including a base substrate 110, which includes a first rigid part A1, a first soft part A2 outside of the first rigid part A1 and a bent end, a first light emitting element 150 on the base substrate 110, a horizontal stretchable line 145, which is connected to the pixel and disposed in the first soft part A2, and a pad 146, which is disposed on a first surface of the bent end of the base substrate 110, and an organic material pattern 160, which is disposed on a second surface of the bent end of the base substrate 110.

The stretchable display device 400 may further include a first soft substate 330 under the base substate 110, a first adhesive layer 340 between the first soft substrate 330 and the base substrate 110, a second soft substrate 350 on the light emitting diode 150 and a second adhesive layer 360 between the second soft substrate 350 and the light emitting diode 150.

Two surface of the organic material pattern 160 contacts the base substrate 110, and the other two surface of the organic material pattern 160 contacts the first adhesive layer 340.

The stretchable display device 400 can be fabricated by removing the carrier substrate 102 and the inorganic sacrificing layer 104 from the first panel PN1 (e.g., a process in FIG. 4G) without an attaching process of the first and second panels PN1 and PN2 (e.g., a process in FIG. 4F) and attaching the first and second soft substrates 330 and 350 to the base substrate 110 and the light emitting diode 150 using the first and second adhesive layers 340 and 360.

In the stretchable display device 400, an end of the base substrate 110 is bent.

Accordingly, the first adhesive layer 340 may have a first thickness at a center of the display panel and/or a center of the base substrate 110 and a second thickness, which is smaller than the first thickness, at an edge of the display panel and/or an edge of the base substrate 110.

The first soft substrate 330 may have a first distance from the base substrate 110 at a center of the display panel (e.g., a center of the base substrate 110 or a center of the stretchable display device 400) and a second distance, which is smaller than the first distance, from the base substrate 110 at an edge of the display panel (e.g., an edge of the base substrate 110 or an edge of the stretchable display device 400).

In the stretchable display device 400, at least one of the insulating layers on the base substrate 110 in the first soft part A2 are removed. Accordingly, the second adhesive layer 360 may have a fifth thickness at a center of the base substrate 110 and a sixth thickness, which is greater than the fifth thickness, at an edge of the base substrate 110.

In an embodiment of the present disclosure, the stretchable display device 400 can be fabricated by the processes in FIGS. 4A to 4E.

In an embodiment of the present disclosure, the stretchable display device 400 can be fabricated by the processes in FIGS. 4A to 4E and the process of attaching the first and second soft substrates 330 and 350 using the first and second adhesive layers 340 and 360.

In the stretchable display device 400, an end of the base substrate 110 is bent so that a narrow bezel structure can be provided. In addition, since the organic material pattern 160, which is disposed at a rear surface of the base substrate 110, supports the pad 146 so that the damage on the base substrate 110 and/or the pad 146 can be prevented. Namely, in the stretchable display device 400, a narrow bezel structure can be provided without a damage on the pad 146 and/or the base substrate 110.

It will be apparent to those skilled in the art that various modifications and variations can be made in the embodiments of the present disclosure without departing from the spirit or scope of the present disclosure. Thus, it is intended that this disclosure cover the modifications and variations provided they come within the scope of the appended claims and their equivalents.

What is claimed is:

1. A stretchable display device, comprising:
a first display panel including:
a first base substrate including a first rigid part, a first soft part and a first bent end;
a first light emitting element on the first base substrate;
a first horizontal stretchable line extending along a first direction; and
a first pad disposed on a first surface of the first base substrate and on the first bent end; and
a first organic material pattern disposed on a second surface of the first base substrate and on the first bent end,
wherein a first pixel is provided at the first rigid part, and the first soft part is disposed outside the first rigid part,
wherein the first horizontal stretchable line is connected to the first pixel and disposed on the first soft part, and
wherein the first pad is connected to an end of the first horizontal stretchable line.

2. The stretchable display device according to claim 1, further comprising:
a second display panel including:
a second base substrate including a second rigid part, a second soft part and a second bent end;
a second light emitting element on the second base substrate;
a second horizontal stretchable line extending along a second direction; and
a second pad disposed on a first surface of the second base substrate and on the second bent end; and
a second organic material pattern disposed on a second surface of the second base substrate and on the second bent end,
wherein a second pixel is provided at the second rigid part, and the second soft part is disposed outside the second rigid part,
wherein the second horizontal stretchable line is connected to the second pixel and disposed on the second soft part,
wherein the second pad is connected to an end of the second horizontal stretchable line, and
wherein the second direction is opposite to the first direction.

3. The stretchable display device according to claim 2, further comprising:
a first metal bonding pattern positioned between the first and second pads.

4. The stretchable display device according to claim 3, further comprising:
a first organic bonding pattern corresponding to the first metal bonding pattern.

5. The stretchable display device according to claim 2, wherein a thickness of the first organic material pattern is equal to or greater than a thickness of the first base substrate, and
wherein a thickness of the second organic material pattern is equal to or greater than a thickness of the second base substrate.

6. The stretchable display device according to claim 2, further comprising:
a first soft substrate under the first and second base substrates; and
a second soft substrate on the first and second light emitting elements.

7. The stretchable display device according to claim 6, wherein the first soft substrate has a first distance from the first base substrate at a center of the first display panel and a second distance from the first base substrate at an edge of the first display panel, and the second distance is smaller than the first distance, and
wherein the first soft substrate has a third distance from the second base substrate at a center of the second display panel and a fourth distance from the second base substrate at an edge of the second display panel, and the fourth distance is smaller than the third distance.

8. The stretchable display device according to claim 6, further comprising:
a first adhesive layer between the first soft substrate and each of the first and second base substrates; and
a second adhesive layer between the second soft substrate and each of the first and second light emitting elements.

9. The stretchable display device according to claim 8, wherein the first adhesive layer has a first thickness at a center of the first display panel and a second thickness at an edge of the first display panel, and the second thickness is smaller than the first thickness, and
wherein the second adhesive layer has a third thickness at a center of the second display panel and a fourth thickness at an edge of the second display panel, and the fourth thickness is greater than the third thickness.

10. The stretchable display device according to claim 1, further comprising:
a first soft substrate under the first base substrate; and
a second soft substrate on the first light emitting element.

11. The stretchable display device according to claim 10, wherein the first soft substrate has a first distance from the first base substrate at a center of the first display panel and a second distance from the first base substrate at an edge of the first display panel, and the second distance is smaller than the first distance.

12. The stretchable display device according to claim 10, further comprising:
a first adhesive layer between the first soft substrate and the first base substrate; and
a second adhesive layer between the second soft substrate and the first light emitting element.

13. The stretchable display device according to claim 12, wherein the first adhesive layer has a first thickness at a center of the first base substrate and a second thickness at an edge of the first base substrate, and the second thickness is smaller than the first thickness.

14. A method of fabricating a stretchable display device; comprising:
forming a first inorganic sacrificing layer on a first surface of a first carrier substrate;
forming a first panel on the first inorganic sacrificing layer, wherein the first panel includes:
a first base substrate including a first rigid part, a first soft part and a first bent end; a first light emitting element on the first base substrate; and a first horizontal stretchable line disposed on the first soft part, and wherein a first pixel is provided at the first rigid part, and the first horizontal stretchable line is connected to the first pixel;
forming a first hole exposing the first base substrate by etching the first carrier substrate and the first inorganic sacrificing layer at a portion of the first soft part;
forming a first organic material pattern in the first hole;
bending the first base substrate based on the first hole; and
irradiating a laser to the first hole to remove a portion of the first carrier substrate, a portion of the first inorganic sacrificing layer, a portion of the first base substrate, and a portion of the first horizontal stretchable line.

15. The method according to claim 14, further comprising:
forming a second inorganic sacrificing layer on a first surface of a second carrier substrate;
forming a second panel on the second inorganic sacrificing layer, wherein the second panel includes: a second base substrate including a second rigid part, a second soft part and a second bent end; a second light emitting element on the second base substrate; and a second horizontal stretchable line disposed on the second soft part, and wherein a second pixel is provided at the second rigid part, and the second horizontal stretchable line is connected to the second pixel;
forming a second hole exposing the second base substrate by etching the second carrier substrate and the second inorganic sacrificing layer at a portion of the second soft part;
forming a second organic material pattern in the second hole;
bending the second base substrate based on the second hole;
irradiating a laser to the second hole to remove a portion of the second carrier substrate, a portion of the second inorganic sacrificing layer, a portion of the second base substrate, and a portion of the second horizontal stretchable line;
attaching the first and second panels, wherein an end of the first horizontal stretchable line faces an end of the second horizontal stretchable line; and
irradiating a laser to a second surface of the first and second carrier substrates to separate the first carrier substrate and the first inorganic sacrificing layer from the first base substrate and the second carrier substrate and the second inorganic sacrificing layer from the second base substrate.

16. The method according to claim 15, further comprising:
attaching a first soft substrate to the first and second base substrates using a first adhesive layer; and
attaching a second soft substrate to the first and second light emitting elements using a second adhesive layer.

17. The method according to claim 15, wherein the attaching the first and second panels comprises:
forming a metal bonding pattern between the end of the first horizontal stretchable line and the end of the second horizontal stretchable line.

18. The method according to claim 17, wherein the attaching the first and second panels comprises:
forming an organic bonding pattern covering the metal bonding pattern.

19. The method according to claim 14, further comprising:
irradiating a laser to a second surface of the first carrier substrate to separate the first carrier substrate and the first inorganic sacrificing layer from the first base substrate.

20. The method according to claim 19, further comprising:
attaching a first soft substrate to the first base substrate using a first adhesive layer; and
attaching a second soft substrate to the first light emitting element using a second adhesive layer.
